(19) United States
(12) Patent Application Publication
(10) Pub. No.: US 2025/0017110 A1
(43) Pub. Date: Jan. 9, 2025

(54) THERMOELECTRIC COOLING CHIP AND PACKAGE STRUCTURE THEREOF

(71) Applicant: Realtek Semiconductor Corp., HsinChu (TW)

(72) Inventor: Chih-Yen Su, HsinChu (TW)

(73) Assignee: Realtek Semiconductor Corp., HsinChu (TW)

(21) Appl. No.: 18/668,227

(22) Filed: May 19, 2024

(30) Foreign Application Priority Data
Jul. 6, 2023 (TW) 112125282

(51) Int. Cl. H10N 10/17; H01L 23/38; H01L 23/42; H10N 10/82

(52) U.S. Cl. CPC H10N 10/17; H01L 23/38; H01L 23/42; H10N 10/82

(57) ABSTRACT

A thermoelectric cooling chip including a substrate; a buffer layer on a surface of the substrate; a first etching stop layer on the buffer layer; a dielectric layer on the first etching stop layer; a first conductivity type semiconductor layer in the dielectric layer; a first wire layer in the dielectric layer and directly contacts the sidewall of the first conductivity type semiconductor layer; a second etching stop layer on the first conductivity type semiconductor layer; a second wire layer in the dielectric layer and the second etching stop layer and directly contacts the sidewall of the first conductivity type semiconductor layer; a second conductivity type semiconductor layer on the first conductivity type semiconductor layer; and a third wire layer on the second wire layer, and directly contacts the sidewall of the second conductive type semiconductor layer.

### BACKGROUND OF THE INVENTION

### 1. Field of the Invention

The invention relates to the field of semiconductor technology, in particular to a thermoelectric cooling chip and a package structure thereof.

### 2. Description of the Prior Art

As known in the art, a thermoelectric cooling structure is constructed by using thermoelectric materials, and the cooling effect is achieved by inputting electric current. The thermoelectric cooling structure typically includes pairs of p-type and n-type semiconductors pellets connected electrically in series and thermally in parallel. The P-type semiconductor is connected to the N-type semiconductor with metal. When the current passes through the PN couple, only the high-energy holes in the P-type semiconductor can overcome the energy barrier. In the N-type semiconductor, only high-energy electrons can overcome the energy barrier.

The heat can be taken away by the hot carriers and removed from the cold side to the hot side of the metal that connects the P-type semiconductor and the N-type semiconductor. The temperature difference of the metal can be adjusted according to the current passing through the PN couple, whereby the temperature of the heat source can be controlled.

Conventionally, the P-type and N-type semiconductors pellets of a thermoelectric cooling device are arranged in a two-dimensional, planar manner, which makes the thermoelectric cooling device larger in size. Therefore, the conventional thermoelectric cooling device can only be installed externally on the periphery of the IC package to help the package dissipate heat, and cannot be disposed within the IC package to directly contact the heat source chip encapsulated inside the IC package.

### SUMMARY OF THE INVENTION

One object of the present invention is to provide an improved an improved thermoelectric cooling chip and a package structure thereof, which can improve the shortcomings or deficiencies of the prior art.

One aspect of the invention provides a thermoelectric cooling chip including a substrate; a buffer layer disposed on a surface of the substrate; a first etching stop layer disposed on the buffer layer; a dielectric layer disposed on the first etching stop layer; a first conductivity type semiconductor layer buried in the dielectric layer; a first wiring layer disposed in the dielectric layer and directly contacting a sidewall of the first conductivity type semiconductor layer; a second etching stop layer disposed on the first conductivity type semiconductor layer; a second wiring layer disposed in the dielectric layer and the second etching stop layer, and directly contacting the sidewall of the first conductivity type semiconductor layer; a second conductivity type semiconductor layer disposed on the first conductivity type semiconductor layer; and a third wiring layer disposed on the second wiring layer and directly contacting a sidewall of the second conductive type semiconductor layer.

According to some embodiments, the substrate comprises a silicon substrate.

According to some embodiments, the first conductivity type semiconductor layer is a P-type doped polysilicon layer and the second conductivity type semiconductor layer is an N-type doped polysilicon layer.

According to some embodiments, the first conductivity type semiconductor layer is an N-type doped polysilicon layer and the second conductivity type semiconductor layer is a P-type doped polysilicon layer.

According to some embodiments, the buffer layer comprises a silicon oxide layer, the first etching stop layer comprises a silicon nitride layer, and the second etching stop layer comprises a silicon nitride layer.

According to some embodiments, the dielectric layer comprises a silicon oxide layer.

According to some embodiments, the second conductivity type semiconductor layer and the first conductivity type semiconductor layer are electrically isolated by the second etching stop layer.

Another aspect of the invention provides a package structure including a package substrate; a heat source chip comprising an active surface and a passive surface, wherein the active surface is connected to the package substrate; and a thermoelectric cooling chip having a top surface and a bottom surface. The passive surface of the heat source chip is in thermal contact with the top surface of the thermoelectric cooling chip. The top surface of the thermoelectric cooling chip includes a plurality of N-type semiconductor layers and P-type semiconductor layers constructed in a three-dimensional stack and arranged in a ring corresponding to periphery of the heat source chip. A molding compound encapsulates the heat source chip and the thermoelectric cooling chip. The bottom surface of the thermoelectric cooling chip is not covered by the molding compound. A heat sink is disposed on the bottom surface of the thermoelectric cooling chip.

According to some embodiments, the plurality of N-type semiconductor layers and P-type semiconductor layers are electrically connected together in pairs with conductive lines, thereby forming an annular inner heat-absorbing region and an annular outer heat-dissipating region. The outer heat-dissipating region surrounds the inner heat-absorbing region.

According to some embodiments, the top surface of the thermoelectric cooling chip further comprises a metal bonding pad electrically connected to the package substrate through a copper pillar provided in the molding compound.

According to some embodiments, the thermoelectric cooling chip further comprises a through-silicon via, wherein one end of the through-silicon via is exposed on the bottom surface of the thermoelectric cooling chip, and the other end is disposed in proximity to the outer heat-dissipating region.

According to some embodiments, a thermal interface material is provided between the heat sink and the bottom surface of the thermoelectric cooling chip.

Still another aspect of the invention provides a package structure including a package substrate; a heat source chip comprising an active surface and a passive surface; and a thermoelectric cooling chip having a top surface and a bottom surface. The passive surface of the heat source chip is in thermal contact with the top surface of the thermoelectric cooling chip. The top surface of the thermoelectric cooling chip includes a plurality of N-type semiconductor layers and P-type semiconductor layers constructed in a three-dimensional stack and arranged in a ring shape corresponding to periphery of the heat source chip. The bottom surface of the thermoelectric cooling chip is fixed on the package substrate. A molding compound encapsulates the heat source chip and the thermoelectric cooling chip. A redistribution layer is disposed on the molding compound and the active surface of the heat source chip. A heat sink is disposed on the redistribution layer.

According to some embodiments, the plurality of N-type semiconductor layers and P-type semiconductor layers are electrically connected together in pairs with conductive lines, thereby forming an annular inner heat-absorbing region and an annular outer heat-dissipating region, wherein the outer heat-dissipating region surrounds the inner heat-absorbing region.

According to some embodiments, a through-mold via is provided in the molding compound between the redistribution layer and the top surface of the thermoelectric cooling chip. One end of the through-mold via is in thermal contact with the outer heat-dissipating region of the thermoelectric cooling chip.

According to some embodiments, the top surface of the thermoelectric cooling chip further includes a metal bonding pad electrically connected to the package substrate through a bonding wire provided in the molding compound.

According to some embodiments, a thermal interface material is provided between the heat sink and the redistribution layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view of a semiconductor structure comprising a thermoelectric cooling chip and a heat source chip according to an embodiment of the present invention.

FIG. 2 is a schematic cross-sectional view taken along line I-I′ in FIG. 1.

FIG. 3 is a schematic cross-sectional view of a package structure according to an embodiment of the present invention.

FIG. 4 is a schematic cross-sectional view of a package structure according to another embodiment of the present invention.

FIG. 5 to FIG. 17 illustrate an exemplary method of fabricating a thermoelectric cooling chip.

### DETAILED DESCRIPTION

In the following, the details will be explained with reference to the drawings, and the contents in these drawings also form part of the detailed description of the specification, and are illustrated in a specific example description manner in which this embodiment can be implemented. The following examples have described enough details to enable those of ordinary skill in the art to implement them. Of course, other embodiments may be adopted, or any structural, logical, and electrical changes may be made without departing from the embodiments described in the text. Therefore, the detailed description below should not be considered as a limitation, on the contrary, the embodiments contained therein will be defined by the scope of the attached patent application.

It should be understood that although the terms “first”, “second”, etc. may be used herein to describe various elements, regions, layers and/or sections, these elements, regions, layers and/or sections should not be limited by these terms. These terms are only used to distinguish one element, region, layer or section from another element, region, layer or section. Accordingly, the first element, region, layer or section discussed below may be referred to as the second element, region, layer or section without departing from the teachings of the exemplary embodiments.

The instant disclosure pertains to a package structure comprising a thermoelectric cooling chip, wherein the thermoelectric cooling chip and the heat source chip can be assembled within one single package. The thermoelectric cooling chip may be manufactured in the form of semiconductor thin films, and the number of P-type semiconductors and N-type semiconductors can be increased in a three-dimensional stacking manner, thereby increasing the heat-absorbing area and heat dissipation efficiency. The instant disclosure utilizes packaging technology to assembly the thermoelectric cooling chip and the heat source chip together so as to form a single package structure having the internal thermoelectric cooling chip, so as to solve the deficiency of the prior art.

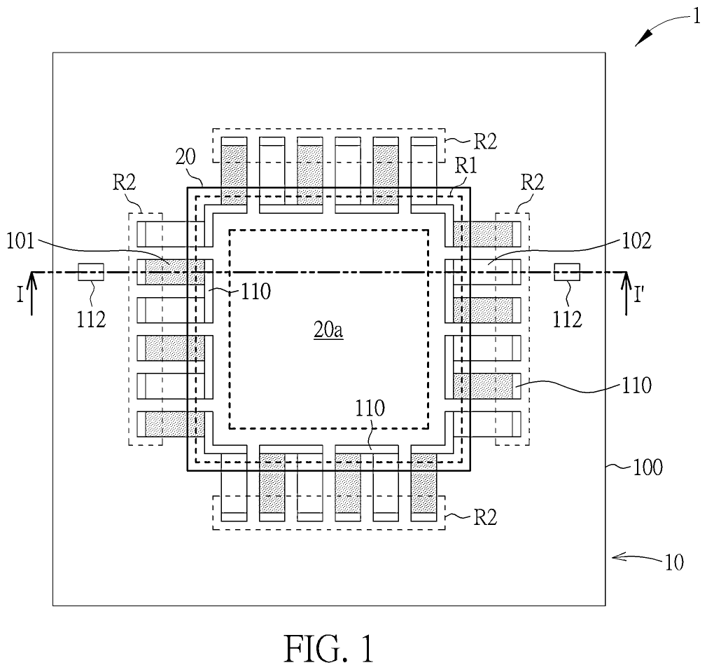

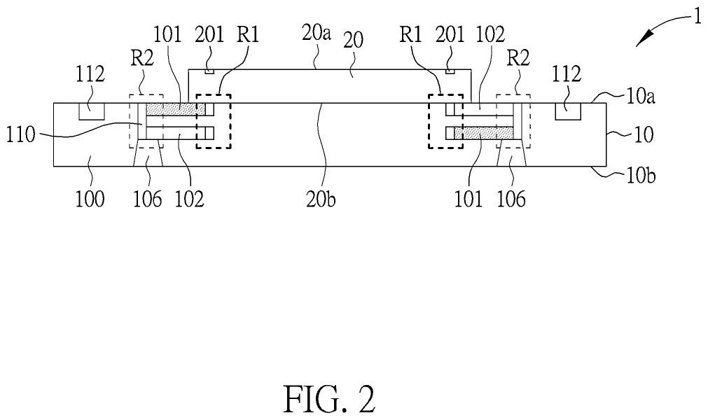

Please refer to FIG. 1 and FIG. 2, wherein FIG. 1 is a perspective view of a semiconductor structure comprising a thermoelectric cooling chip and a heat source chip according to an embodiment of the present invention, and FIG. 2 is a schematic cross-sectional view taken along line I-I′ in FIG. 1. As shown in FIG. 1 and FIG. 2, the semiconductor structure 1 includes a thermoelectric cooling chip 10 and a heat source chip 20 disposed on the top surface 10a of the thermoelectric cooling chip 10. According to an embodiment of the present invention, the heat source chip 20 includes an active surface 20a and a passive surface 20b, wherein a plurality of input/output (I/O) pads 201 may be disposed on the active surface 20a. The thermoelectric cooling chip 10 includes a substrate 100. According to an embodiment of the present invention, for example, the substrate 100 may be a silicon substrate.

According to an embodiment of the present invention, for example, the thermoelectric cooling chip 10 and the heat source chip 20 may be silicon chips. According to an embodiment of the present invention, for example, the heat source chip 20 may include, but not limited to, an application processor (AP) chip, a central processing unit (CPU) chip, a graphics processing unit (GPU) chip, a System on a Chip (SoC), etc.

According to an embodiment of the present invention, the passive surface 20b of the heat source chip 20 is in direct thermal contact with the top surface 10a of the thermoelectric cooling chip 10. According to an embodiment of the present invention, the heat source chip 20 can be fixed on the top surface 10a of the thermoelectric cooling chip 10 by any suitable thermally conductive method including, for example, adhesive, direct bonding or the like. According to an embodiment of the present invention, the top surface 10a of the thermoelectric cooling chip 10 includes N-type semiconductor layers 101 and P-type semiconductor layers 102 formed in a three-dimensional stacking manner, which are arranged in a ring corresponding to the periphery of the heat source chip 20.

According to an embodiment of the present invention, the pair of N-type semiconductor layer 101 and the P-type semiconductor layer 102 are manufactured by semiconductor manufacturing process, and are electrically connected to each other by conductive line 110, thus constituting the inner heat-absorbing region R1 and the outer heat-dissipating region R2 as indicated by the dotted line, wherein the outer heat-dissipating region R2 surrounds the inner heat-absorbing region R1. According to an embodiment of the present invention, for example, the conductive line 110 may include a copper wire, but is not limited thereto. According to an embodiment of the present invention, the N-type semiconductor layer 101 and the P-type semiconductor layer 102 on the top surface 10a of the thermoelectric cooling chip 10 may be a two-layer stack or a multi-layer stack having more than two semiconductor layers arranged in an alternating manner.

According to an embodiment of the present invention, the top surface 10a of the thermoelectric cooling chip 10 may further include metal bonding pads 112. The metal bonding pads 112 are electrically connected to the conductive lines 110. The metal bonding pads 112 may be connected to external signals and current provided for the thermoelectric cooling chip 10 may pass through the metal bonding pads 112. According to an embodiment of the present invention, for example, the substrate 100 of the thermoelectric cooling chip 10 may further include a through silicon via (TSV) 106 for heat conduction. One end of the through silicon via 106 may be exposed from the bottom surface 10b of the thermoelectric cooling chip 10. The other end of the through silicon via 106 may be positioned in proximity to the outer heat-dissipating region R2. Those skilled in the art should understand that the size or quantity of each element and region shown in the figures is for illustrative purposes only and is not necessarily drawn to scale.

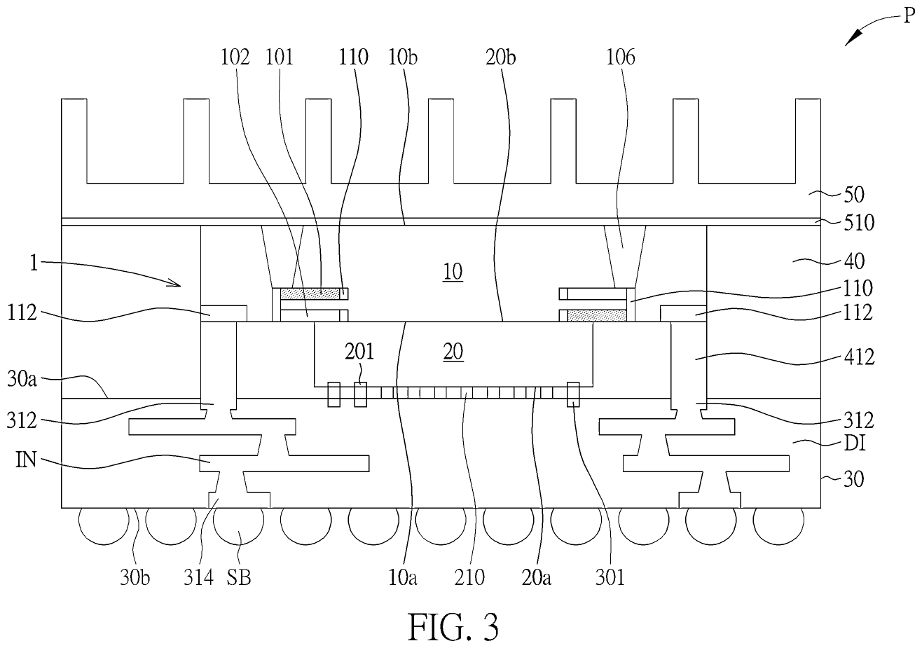

Please refer to FIG. 3, which is a schematic cross-sectional view of a package structure according to an embodiment of the present invention. As shown in FIG. 3, the package structure P includes a package structure 30 and a semiconductor structure 1 disposed on the package structure 30. The semiconductor structure 1, as described in FIG. 1 and FIG. 2, includes the thermoelectric cooling chip 10 and the heat source chip 20 disposed on the top surface 10a of the thermoelectric cooling chip 10. According to an embodiment of the present invention, the heat source chip 20 includes an active surface 20a and a passive surface 20b, wherein a plurality of input/output pads 201 may be disposed on the active surface 20a. The thermoelectric cooling chip 10 includes a substrate 100. According to an embodiment of the present invention, for example, the substrate 100 may be a silicon substrate. According to an embodiment of the present invention, the semiconductor structure 1 is encapsulated by a molding compound 40, and only the bottom surface 10b of the thermoelectric cooling chip 10 is exposed.

According to an embodiment of the present invention, the passive surface 20b of the heat source chip 20 is in direct thermal contact with the top surface 10a of the thermoelectric cooling chip 10. According to an embodiment of the present invention, the heat source chip 20 can be fixed on the top surface 10a of the thermoelectric cooling chip 10 by any suitable thermal conductive method, such as adhesive or direct bonding. According to an embodiment of the present invention, the top surface 10a of the thermoelectric cooling chip 10 includes N-type semiconductor layers 101 and P-type semiconductor layers 102 constructed in a three-dimensional stack and arranged in a ring corresponding to the periphery of the heat source chip 20.

According to an embodiment of the present invention, the N-type semiconductor layer 101 and the P-type semiconductor layer 102 are manufactured by semiconductor manufacturing process. The pair of N-type semiconductor layer 101 and the P-type semiconductor layer 102 are electrically connected to each other by conductive line 110, thereby forming the annular inner heat-absorbing region R1 and the annular outer heat-dissipating region R2. The outer heat-dissipating region R2 surrounds the inner heat-absorbing region R1. According to an embodiment of the present invention, for example, the conductive line 110 may include a copper wire, but is not limited thereto. According to an embodiment of the present invention, the N-type semiconductor layer 101 and the P-type semiconductor layer 102 on the top surface 10a of the thermoelectric cooling chip 10 may be a two-layer stack or a multi-layer stack having more than two semiconductor layers arranged in an alternating manner.

According to an embodiment of the present invention, the top surface 10a of the thermoelectric cooling chip 10 further includes metal bonding pads 112. The metal bonding pads 112 are electrically connected to the conductive lines 110. The metal bonding pads 112 may be connected to external signals and current provided for the thermoelectric cooling chip 10 may pass through the metal bonding pads 112. According to an embodiment of the present invention, for example, the substrate 100 of the thermoelectric cooling chip 10 may further include a through silicon via 106 for heat conduction. One end of the through silicon via 106 may be exposed from the bottom surface 10b of the thermoelectric cooling chip 10. The other end of the through silicon via 106 may be positioned in proximity to the outer heat-dissipating region R2.

According to an embodiment of the present invention, the semiconductor structure 1 is mounted onto the top surface 30a of the package structure 30 in a flip-chip fashion. According to an embodiment of the present invention, for example, the active surface 20a of the heat source chip 20 of the semiconductor structure 1 is electrically connected to the corresponding bonding pads 301 on the top surface 30a of the package structure 30 through the conductive connecting elements 210. According to some embodiments of the present invention, an underfill may be optionally filled between the top surface 30a of the package substrate 30 and the active surface 20a of the heat source chip 20. According to an embodiment of the present invention, for example, the conductive connecting elements 210 may include, but is not limited to, solder, solder balls, bumps, micro bumps, copper pillars, copper bumps or the like.

According to an embodiment of the present invention, the package structure 30 may include a cored substrate or a coreless substrate. According to other embodiments of the present invention, the package structure 30 may include an interposer substrate. According to an embodiment of the present invention, the package structure 30 may include multiple build-up films DI and multiple wiring layers IN. According to an embodiment of the present invention, for example, the build-up films DI may include bismaleimide triazine (BT) resin or Ajinomoto build-up film (ABF), but not limited to thereto. According to an embodiment of the present invention, for example, the wiring layers IN may include copper, but is not limited thereto.

According to an embodiment of the present invention, bonding pads 312 are provided on the top surface 30a of the package substrate 30, which are electrically connected to the metal bonding pads 112 on the top surface 10a of the thermoelectric cooling chip 10 through the copper pillar 412 embedded in the molding compound 40. Ball pads 314 are further disposed on the bottom surface 30b of the package substrate 30, and solder balls SB, for example, ball grid array (BGA) solder balls, are respectively disposed on the ball pads 314.

According to an embodiment of the present invention, a heat sink 50 is further disposed on the bottom surface 10b of the thermoelectric cooling chip 10. The material of the heat sink 50 may include, for example, aluminum, copper, graphene or other suitable high thermal conductivity materials. According to an embodiment of the present invention, a thermal interface material (TIM) 510 may be provided between the heat sink 50 and the bottom surface 10b of the thermoelectric cooling chip 10 to improve the heat conduction efficiency at the interface.

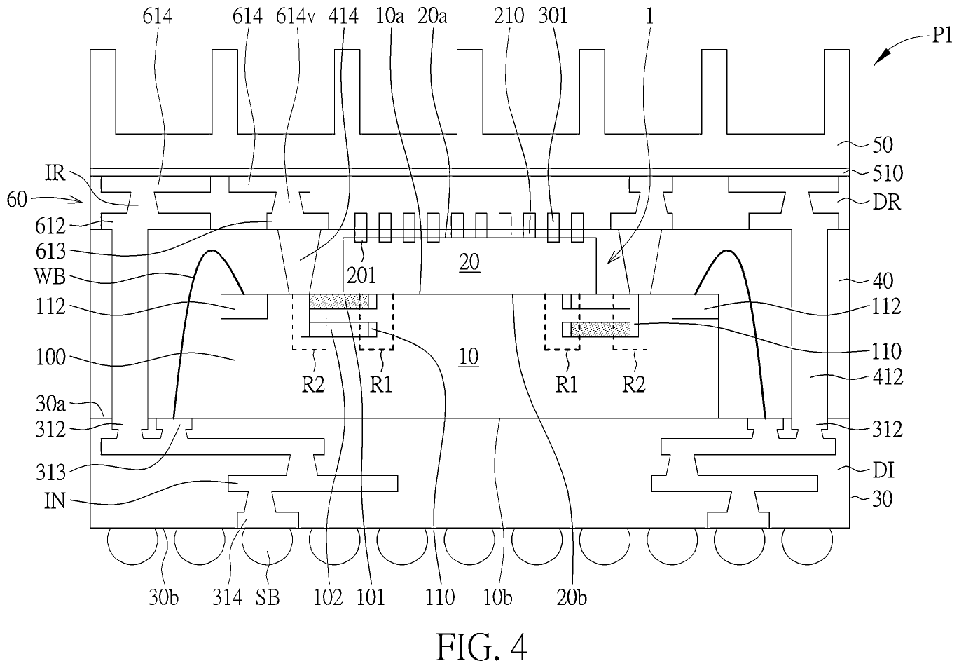

Please refer to FIG. 4, which is a cross-sectional schematic diagram of a package structure according to another embodiment of the present invention, wherein like regions, elements, and layers are designated by like numeral numbers or labels. As shown in FIG. 4, likewise, the package structure P1 includes a package substrate 30 and a semiconductor structure 1 disposed on the package substrate 30, wherein the semiconductor structure 1, as described in FIG. 1 and FIG. 2, includes a thermoelectric cooling chip 10 and a heat source chip 20 disposed on the top surface 10a of the thermoelectric cooling chip 10. According to an embodiment of the present invention, the heat source chip 20 includes an active surface 20a and a passive surface 20b, wherein a plurality of input/output pads 201 may be disposed on the active surface 20a. The thermoelectric cooling chip 10 includes a substrate 100. According to an embodiment of the present invention, for example, the substrate 100 may be a silicon substrate. According to an embodiment of the present invention, the semiconductor structure 1 is encapsulated by a molding compound 40.

According to an embodiment of the present invention, the passive surface 20b of the heat source chip 20 is in direct thermal contact with the top surface 10a of the thermoelectric cooling chip 10. According to an embodiment of the present invention, the heat source chip 20 can be fixed on the top surface 10a of the thermoelectric cooling chip 10 by any suitable heat conduction method, such as adhesive or direct bonding. According to an embodiment of the present invention, the top surface 10a of the thermoelectric cooling chip 10 includes N-type semiconductor layers 101 and P-type semiconductor layers 102 formed in a three-dimensional stack and arranged in a ring corresponding to the periphery of the heat source chip 20.

According to an embodiment of the present invention, the pair of N-type semiconductor layer 101 and the P-type semiconductor layer 102 are manufactured by semiconductor manufacturing process, and are electrically connected to each other by conductive lines 110, thereby forming the annular inner heat-absorbing region R1 and the annular outer heat-dissipating region R2. The outer heat-dissipating region R2 surrounds the inner heat-absorbing region R1. According to an embodiment of the present invention, for example, the conductive line 110 may include a copper wire, but is not limited thereto. According to an embodiment of the present invention, the N-type semiconductor layer 101 and the P-type semiconductor layer 102 on the top surface 10a of the thermoelectric cooling chip 10 may be a two-layer stack or a multi-layer stack having more than two semiconductor layers arranged in an alternating manner.

According to an embodiment of the present invention, the top surface 10a of the thermoelectric cooling chip 10 further includes metal bonding pads 112. The metal bonding pads 112 may be electrically connected to the conductive line 110. The metal bonding pads 112 may be connected to external signals and current provided for the thermoelectric cooling chip 10 may pass through the metal bonding pads 112. According to an embodiment of the present invention, for example, the metal bonding pads 112 of the thermoelectric cooling chip 10 can be electrically connected to the corresponding bonding pads 313 on the top surface 30a of the package structure 30 through bonding wires WB. According to an embodiment of the present invention, for example, the bonding wire WB may include a gold wire or a copper wire, but is not limited thereto.

According to an embodiment of the present invention, the bottom surface 10b of the thermoelectric cooling chip 10 of the semiconductor structure 1 can be adhered onto the top surface 30a of the package structure 30. According to an embodiment of the present invention, the package structure 30 may be a cored substrate or a coreless substrate. According to other embodiments of the present invention, the package substrate 30 may be an interposer substrate. According to an embodiment of the present invention, the package structure 30 may include multiple build-up films DI and multiple wiring layers IN. According to an embodiment of the present invention, for example, the build-up film DI may include BT resin or ABF, but is not limited thereto. According to an embodiment of the present invention, for example, the wiring layer IN may contain copper, but is not limited thereto. Ball pads 314 are disposed on the bottom surface 30 b of the package substrate 30, and solder balls SB, for example, BGA solder balls, are respectively disposed on the ball pads 314.

According to an embodiment of the present invention, a re-distribution layer (RDL) 60 is further disposed on the molding compound 40 and the active surface 20a of the heat source chip 20. According to an embodiment of the present invention, the redistribution layer 60 may include an insulating layer DR and an interconnection layer IR, wherein the interconnection layer IR of the redistribution layer 60 may be electrically connected to the input/output pads 201 on the active surface 20a of the heat source chip 20, and therefore has the function of transmitting signals. According to an embodiment of the present invention, the insulating layer DR may include silicon oxide, silicon nitride, or the like. According to an embodiment of the present invention, the interconnection layer IR may comprise copper. According to an embodiment of the present invention, the redistribution layer 60 further includes a bonding pad 612, for example, a copper pad, which is electrically connected to the bonding pad 312 on the top surface 30a of the package substrate 30 through the copper pillar 412 embedded in the molding compound 40. A through mold via (TMV) 414 may be formed in the molding compound 40 between the redistribution layer 60 and the top surface 10a of the thermoelectric cooling chip 10, wherein one end of the through mold via 414 is in thermal contact with the outer heat-dissipating region R2 of the thermoelectric cooling chip 10.

According to an embodiment of the present invention, a heat sink 50 is further disposed on the redistribution layer 60. The material of the heat sink 50 may include, for example, aluminum, copper, graphene or other suitable materials with high thermal conductivity. According to an embodiment of the present invention, a thermal interface material 510 may be provided between the heat sink 50 and the redistribution layer 60 to improve the thermal conduction efficiency at the interface. According to an embodiment of the present invention, the heat of the outer heat-dissipating region R2 of the thermoelectric cooling chip 10 can be transferred to the heat sink 50 through the through-mold via 414, the thermal pad 613, the thermal via 614v, and the thermal pad 614 in the redistribution layer 60. According to some embodiments of the present invention, the bonding wire WB may be omitted, and the through-mold via 414 may be directly located on the metal bonding pad 112 for signal transmission.

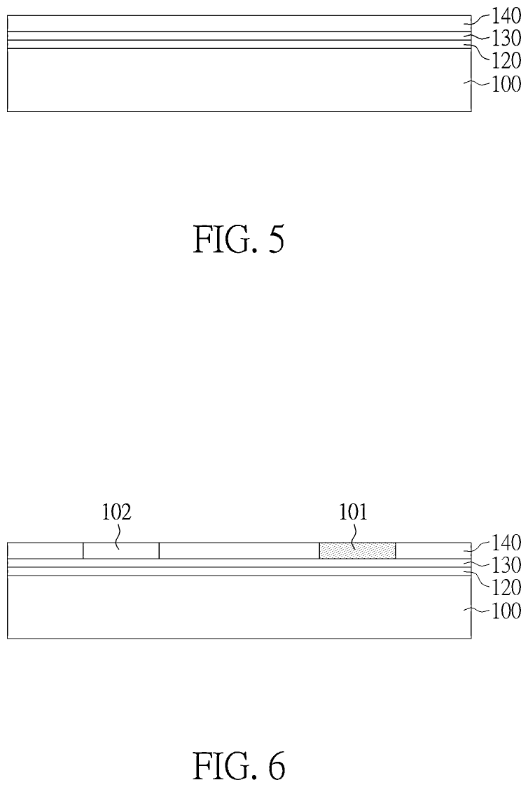

FIG. 5 to FIG. 17 illustrate an exemplary method of fabricating a thermoelectric cooling chip. As shown in FIG. 5, a substrate 100, such as a silicon substrate, is provided, and then a silicon oxide layer 120, a silicon nitride layer 130 and a polysilicon layer 140 are sequentially deposited on the substrate 100. According to an embodiment of the present invention, the silicon oxide layer 120 can be used as a buffer layer, and the silicon nitride layer 130 can be used as an etching stop layer. As shown in FIG. 6, a lithography process and an ion implantation process are then performed to form an N-type semiconductor layer 101 and a P-type semiconductor layer 102 at predetermined positions in the polysilicon layer 140. As shown in FIG. 7, the polysilicon layer 140 except for the N-type semiconductor layer 101 and the P-type semiconductor layer 102 is removed by etching to expose part of the surface of the silicon nitride layer 130.

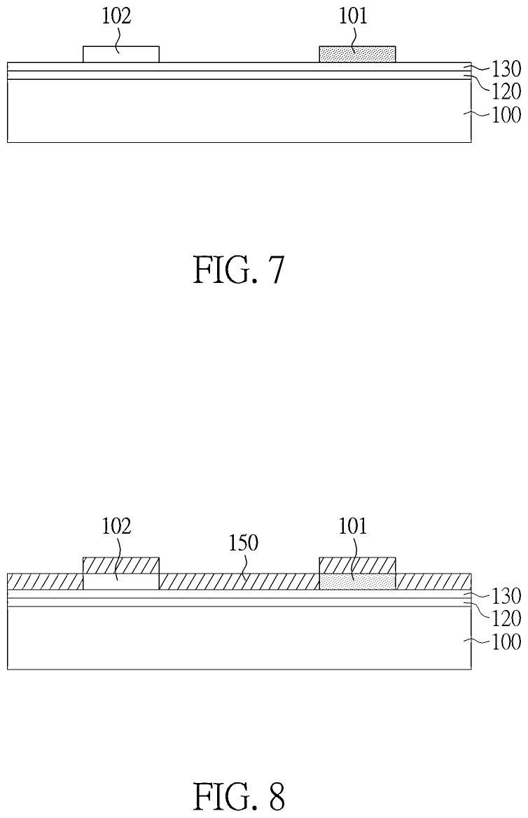

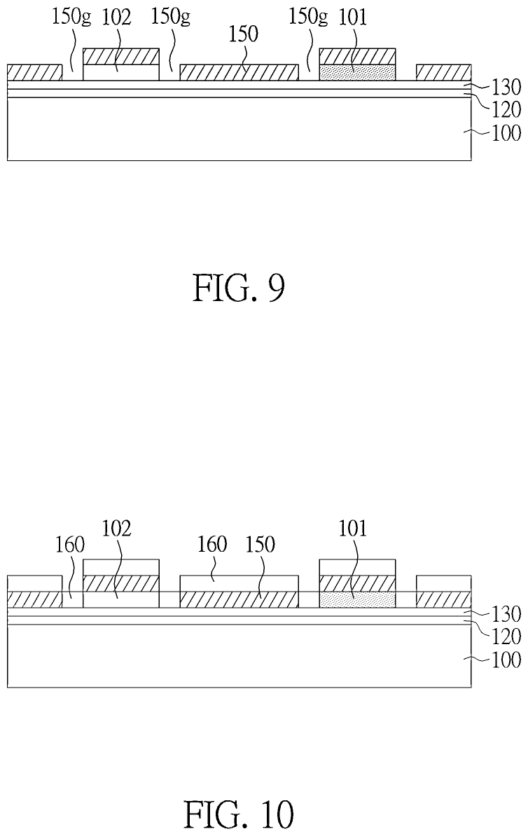

As shown in FIG. 8, for example, a chemical vapor deposition (CVD) process is then performed to conformally deposit a sacrificial layer 150 on the silicon nitride layer 130, the N-type semiconductor layer 101, and the P-type semiconductor layer 102. The sacrificial layer 150 may be, for example, a silicon oxide layer, but not limited thereto. As shown in FIG. 9, a lithography process and a dry etching process may be performed to form an opening 150g in the sacrificial layer 150, so that the opening 150g exposes the sidewalls of the N-type semiconductor layer 101 and the P-type semiconductor layer 102.

As shown in FIG. 10, a metal layer 160 is formed on the sacrificial layer 150 and in the opening 150g by using a sputtering process or a physical vapor deposition (PVD) process. The metal layer 160 may comprise copper, titanium, cobalt, nickel, or tungsten, but not limited thereto. Optionally, the sidewalls of the N-type semiconductor layer 101 and the P-type semiconductor layer 102 may be reacted to form a metal silicide. As shown in FIG. 11, the sacrificial layer 150 and the metal layer 160 on the sacrificial layer 150 are then removed to form the first wiring layer MS1.

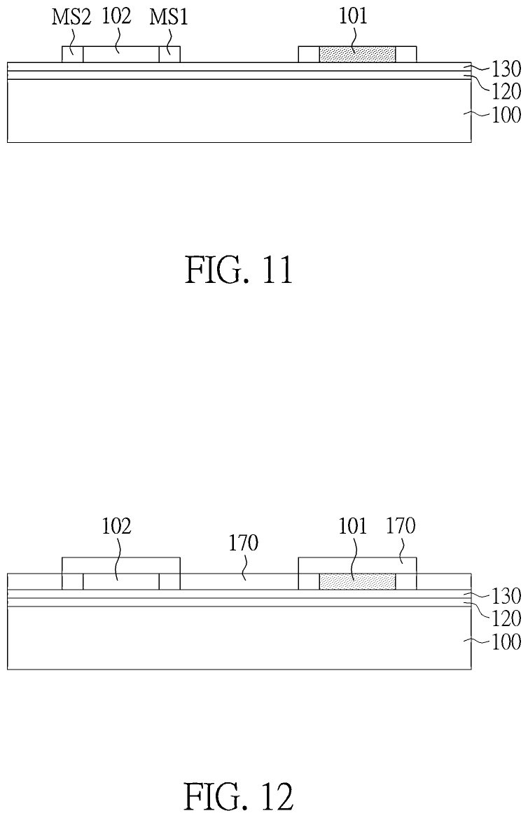

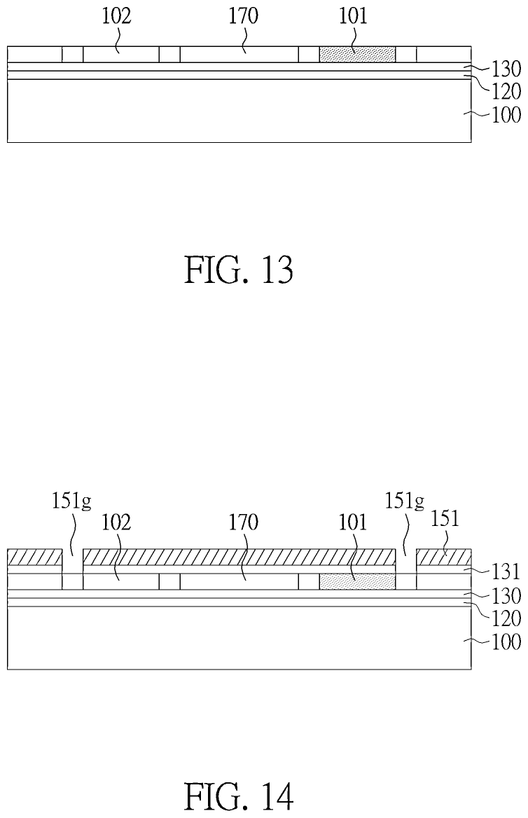

As shown in FIG. 12, a silicon oxide layer 170 is then deposited on the entire surface to conformally cover the silicon nitride layer 130, the first wire layer MS1, the N-type semiconductor layer 101 and the P-type semiconductor layer 102. As shown in FIG. 13, a planarization process, such as a chemical mechanical polishing (CMP) process, is performed to remove a part of the thickness of the silicon oxide layer 170, so that the polished surface of the silicon oxide layer 170 is coplanar with the surface of the N-type semiconductor layer 101 and the surface of the P-type semiconductor layer 102.

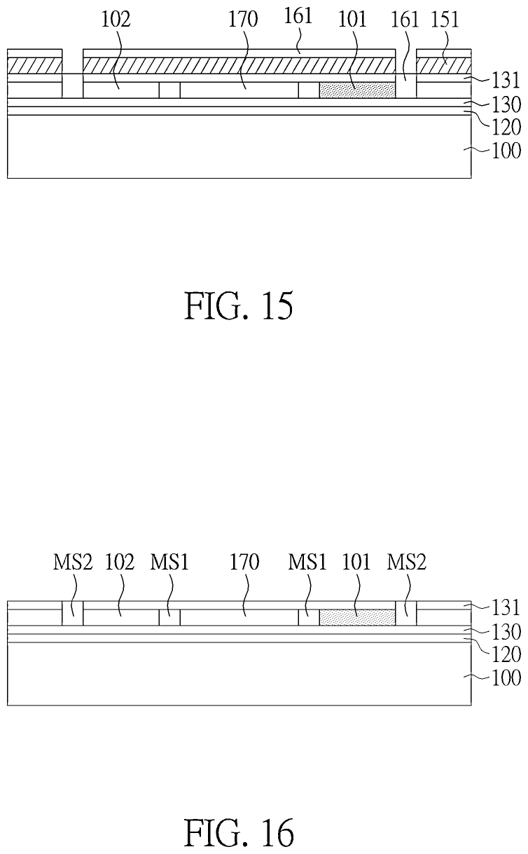

As shown in FIG. 14, a silicon nitride layer 131 and a sacrificial layer 151 are sequentially deposited on the surface of the silicon oxide layer 170 and the surfaces of the N-type semiconductor layer 101 and the P-type semiconductor layer 102. Openings 151g are then formed in the sacrificial layer 151. The opening 151g exposes the first wire layer MS1 that needs to be electrically connected to another semiconducting layer. As shown in FIG. 15, a metal layer 161 is formed on the sacrificial layer 151 and in the opening 151g. As shown in FIG. 16, the sacrificial layer 151 and the metal layer 161 on the sacrificial layer 151 are then removed to form a second wiring layer MS2. At this point, the first wire layer MS1 is covered by the silicon nitride layer 131, while the second wire layer MS2 is not covered by the silicon nitride layer 131.

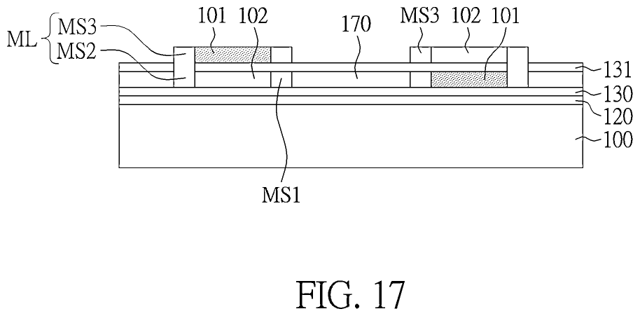

As shown in FIG. 17, the steps in FIG. 5 to FIG. 11 may be repeated to form a three-dimensional stacked structure of N-type semiconductor layer 101 and P-type semiconductor layer 102 and a third wiring layer MS3, wherein the second wiring layer MS2 and the third wire layer MS3 constitute an interconnection wire ML electrically connecting the same sides of the upper and lower stacked N-type semiconductor layers 101 and P-type semiconductor layer 102. Subsequently, the planarization process as shown in FIG. 12 and FIG. 13 may be performed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A thermoelectric cooling chip, comprising:
a substrate;
a buffer layer disposed on a surface of the substrate;
a first etching stop layer disposed on the buffer layer;
a dielectric layer disposed on the first etching stop layer;
a first conductivity type semiconductor layer buried in the dielectric layer;
a first wiring layer disposed in the dielectric layer and directly contacting a sidewall of the first conductivity type semiconductor layer;
a second etching stop layer disposed on the first conductivity type semiconductor layer;
a second wiring layer disposed in the dielectric layer and the second etching stop layer, and directly contacting the sidewall of the first conductivity type semiconductor layer;
a second conductivity type semiconductor layer disposed on the first conductivity type semiconductor layer; and
a third wiring layer disposed on the second wiring layer and directly contacting a sidewall of the second conductive type semiconductor layer.

2. The thermoelectric cooling chip according to claim 1, wherein the substrate comprises a silicon substrate.

3. The thermoelectric cooling chip according to claim 1, wherein the first conductivity type semiconductor layer is a P-type doped polysilicon layer and the second conductivity type semiconductor layer is an N-type doped polysilicon layer.

4. The thermoelectric cooling chip according to claim 1, wherein the first conductivity type semiconductor layer is an N-type doped polysilicon layer and the second conductivity type semiconductor layer is a P-type doped polysilicon layer.

5. The thermoelectric cooling chip according to claim 1, wherein the buffer layer comprises a silicon oxide layer, the first etching stop layer comprises a silicon nitride layer, and the second etching stop layer comprises a silicon nitride layer.

6. The thermoelectric cooling chip according to claim 1, wherein the dielectric layer comprises a silicon oxide layer.

7. The thermoelectric cooling chip according to claim 1, wherein the second conductivity type semiconductor layer and the first conductivity type semiconductor layer are electrically isolated by the second etching stop layer.

8. A package structure, comprising:
a package substrate;
a heat source chip comprising an active surface and a passive surface, wherein the active surface is connected to the package substrate;
a thermoelectric cooling chip comprising a top surface and a bottom surface, wherein the passive surface of the heat source chip is in thermal contact with the top surface of the thermoelectric cooling chip, wherein the top surface of the thermoelectric cooling chip comprises a plurality of N-type semiconductor layers and P-type semiconductor layers constructed in a three-dimensional stack and arranged in a ring corresponding to periphery of the heat source chip;
a molding compound encapsulating the heat source chip and the thermoelectric cooling chip, wherein the bottom surface of the thermoelectric cooling chip is not covered by the molding compound; and
a heat sink disposed on the bottom surface of the thermoelectric cooling chip.

9. The package structure according to claim 8, wherein the plurality of N-type semiconductor layers and P-type semiconductor layers are electrically connected together in pairs with conductive lines, thereby forming an annular inner heat-absorbing region and an annular outer heat-dissipating region, wherein the outer heat-dissipating region surrounds the inner heat-absorbing region.

10. The package structure according to claim 8, wherein the top surface of the thermoelectric cooling chip further comprises a metal bonding pad electrically connected to the package substrate through a copper pillar provided in the molding compound.

11. The package structure according to claim 8, wherein the thermoelectric cooling chip further comprises a through-silicon via, wherein one end of the through-silicon via is exposed on the bottom surface of the thermoelectric cooling chip, and the other end is disposed in proximity to the outer heat-dissipating region.

12. The package structure according to claim 8, wherein a thermal interface material is provided between the heat sink and the bottom surface of the thermoelectric cooling chip.

13. A package structure, comprising:
a package substrate;
a heat source chip comprising an active surface and a passive surface;
a thermoelectric cooling chip comprising a top surface and a bottom surface, wherein the passive surface of the heat source chip is in thermal contact with the top surface of the thermoelectric cooling chip, wherein the top surface of the thermoelectric cooling chip comprises a plurality of N-type semiconductor layers and P-type semiconductor layers constructed in a three-dimensional stack and arranged in a ring shape corresponding to periphery of the heat source chip, wherein the bottom surface of the thermoelectric cooling chip is fixed on the package substrate;
a molding compound encapsulating the heat source chip and the thermoelectric cooling chip;
a redistribution layer disposed on the molding compound and the active surface of the heat source chip; and
a heat sink disposed on the redistribution layer.

14. The package structure according to claim 13, wherein the plurality of N-type semiconductor layers and P-type semiconductor layers are electrically connected together in pairs with conductive lines, thereby forming an annular inner heat-absorbing region and an annular outer heat-dissipating region, wherein the outer heat-dissipating region surrounds the inner heat-absorbing region.

15. The package structure according to claim 14, wherein a through-mold via is provided in the molding compound between the redistribution layer and the top surface of the thermoelectric cooling chip, wherein one end of the through-mold via is in thermal contact with the outer heat-dissipating region of the thermoelectric cooling chip.

16. The package structure according to claim 13, wherein the top surface of the thermoelectric cooling chip further comprises a metal bonding pad electrically connected to the package substrate through a bonding wire provided in the molding compound.

17. The package structure according to claim 13, wherein a thermal interface material is provided between the heat sink and the redistribution layer.
